(19) United States
(12) Patent Application Publication
(10) Pub. No.: US 2025/0185287 A1
(43) Pub. Date: Jun. 5, 2025

(54) METHOD OF SILICON CARBIDE SEMICONDUCTOR DEVICE AND SILICON CARBIDE SEMICONDUCTOR DEVICE

(71) Applicant: FUJI ELECTRIC CO., LTD., Kawasaki-shi (JP)

(72) Inventor: Makoto UTSUMI, Matsumoto-city (JP)

(73) Assignee: FUJI ELECTRIC CO., LTD., Kawasaki-shi (JP)

(21) Appl. No.: 18/897,605

(22) Filed: Sep. 26, 2024

(30) Foreign Application Priority Data
Nov. 30, 2023 (JP) 2023-202895

(51) Int. Cl. H01L 29/78; H01L 21/04; H01L 29/16; H01L 29/66

(52) U.S. Cl. CPC H10D 30/668; H01L 21/046; H10D 12/031; H10D 62/8325

(57) ABSTRACT

A method of manufacturing a silicon carbide semiconductor device, includes: forming a base region of a second conductivity-type on a top surface side of a drift layer of a first conductivity-type including silicon carbide; forming a main region of the first conductivity-type on a top surface side of the base region; depositing a gate insulating film in a trench penetrating the main region and the base region; burying a gate electrode inside the trench with the gate insulating film interposed; and forming a main electrode so as to be in contact with the main region, wherein the forming the main region includes implanting impurity ions of the first conductivity-type at a room temperature so as to form a first region including a 4H-structure, and implanting impurity ions of at least one of silicon, carbon, or argon at a room temperature so as to form a second region including a 3C-structure.

### CROSS-REFERENCE TO RELATED APPLICATION

This application claims benefit of priority under 35 USC 119 based on Japanese Patent Application No. 2023-202895 filed on Nov. 30, 2023, the entire contents of which are incorporated by reference herein.

### BACKGROUND OF THE INVENTION

### 1. Field of the Invention

The present disclosure relates to methods of manufacturing silicon carbide semiconductor devices and further to silicon carbide semiconductor devices.

### 2. Description of the Related Art

JP2009-049198A discloses a semiconductor device including an amorphous layer obtained by implantation of impurity ions into a silicon carbide substrate having hexagonal single crystals, in which the amorphous layer is subjected to annealing to be recrystallized into n-type silicon carbide having cubic single crystals, so as to vapor-deposit nickel on the top surface of the n-type silicon carbide to form an electrode.

WO2017/042963A1 discloses a semiconductor device including an n⁻-type epitaxially-grown layer grown on a first main surface of an n⁺-type SiC substrate including 4H-SiC, an n⁺-type source region formed in the n-type epitaxially-grown layer, and an n⁺-type 3C-SiC region and a p⁺-type potential-fixed region each formed in the n⁺-type source region, in which a barrier metal film is formed in contact with the n⁺-type 3C-SiC region and the p⁺-type potential-fixed region, and an electrode for source wiring is further formed on the barrier metal film.

Development of trench-gate silicon carbide semiconductor devices has been promoted that have a configuration in which a source region (a main region) includes 3C-SiC so as to be in ohmic contact with a source electrode (a main electrode).

However, since 3C-SiC has a larger amount of crystal defects and have greater surface roughness than 4H-SiC, such a semiconductor device may cause a drain-source leakage current (Idss).

### SUMMARY OF THE INVENTION

In view of the foregoing problems, the present disclosure provides a method of manufacturing a trench-gate silicon carbide semiconductor device capable of leading a main region to be in ohmic contact with a main electrode and further avoiding a drain-source leakage current, and also a silicon carbide semiconductor device having such a configuration.

An aspect of the present disclosure inheres in a method of manufacturing a silicon carbide semiconductor device, including: forming a base region of a second conductivity-type including silicon carbide on a top surface side of a drift layer of a first conductivity-type including silicon carbide; forming a main region of the first conductivity-type including silicon carbide on a top surface side of the base region; digging a trench to penetrate the main region and the base region; depositing a gate insulating film in the trench; burying a gate electrode inside the trench with the gate insulating film interposed; and forming a main electrode so as to be in contact with the main region, wherein the forming the main region includes: implanting impurity ions of the first conductivity-type at a room temperature so as to form a first region including a 4H-structure on the top surface side of the base region; and implanting impurity ions of at least one of silicon, carbon, or argon at a room temperature so as to form a second region including a 3C-structure to be in contact with the main electrode on a top surface side of the first region.

Another aspect of the present disclosure inheres in a silicon carbide semiconductor device including: a drift layer of a first conductivity-type including silicon carbide; a base region of a second conductivity-type including silicon carbide provided on a top surface side of the drift layer; a main region of the first conductivity-type including silicon carbide provided on a top surface side of the base region; a gate insulating film provided in a trench penetrating the main region and the base region; a gate electrode buried inside the trench with the gate insulating film interposed; and a main electrode provided to be in contact with the main region, wherein the main region includes: a first region including a 4H-structure on the top surface side of the base region; and a second region provided to be in contact with the main electrode on a top surface side of the first region and including a 3C-structure with a proportion of 70% or higher at least on top surface side of the second region.

### BRIEF DESCRIPTION OF THE DRAWINGS

FIG. 1 is a schematic cross-sectional view illustrating an example of a silicon carbide semiconductor device according to a first embodiment;

FIG. 2 is a schematic enlarged cross-sectional view of region A illustrated in FIG. 1;

FIG. 3 is a schematic cross-sectional view illustrating a silicon carbide semiconductor device of a comparative example;

FIG. 4 is a flowchart showing a method of manufacturing the silicon carbide semiconductor device according to the first embodiment;

FIG. 5 is a schematic cross-sectional view for explaining an example of the method of manufacturing the silicon carbide semiconductor device according to the first embodiment;

FIG. 6 is a schematic cross-sectional view continued from FIG. 5, for explaining the example of the method of manufacturing the silicon carbide semiconductor device according to the first embodiment;

FIG. 7 is a schematic cross-sectional view continued from FIG. 6, for explaining the example of the method of manufacturing the silicon carbide semiconductor device according to the first embodiment;

FIG. 8 is a schematic cross-sectional view continued from FIG. 7, for explaining the example of the method of manufacturing the silicon carbide semiconductor device according to the first embodiment;

FIG. 9 is a schematic cross-sectional view continued from FIG. 8, for explaining the example of the method of manufacturing the silicon carbide semiconductor device according to the first embodiment;

FIG. 10 is a schematic cross-sectional view continued from FIG. 9, for explaining the example of the method of manufacturing the silicon carbide semiconductor device according to the first embodiment;

FIG. 11 is a schematic cross-sectional view continued from FIG. 10, for explaining the example of the method of manufacturing the silicon carbide semiconductor device according to the first embodiment;

FIG. 12 is a schematic cross-sectional view continued from FIG. 11, for explaining the example of the method of manufacturing the silicon carbide semiconductor device according to the first embodiment;

FIG. 13 is a schematic cross-sectional view continued from FIG. 12, for explaining the example of the method of manufacturing the silicon carbide semiconductor device according to the first embodiment;

FIG. 14 is a schematic cross-sectional view continued from FIG. 13, for explaining the example of the method of manufacturing the silicon carbide semiconductor device according to the first embodiment;

FIG. 15 is a schematic cross-sectional view continued from FIG. 14, for explaining the example of the method of manufacturing the silicon carbide semiconductor device according to the first embodiment;

FIG. 16 is a flowchart showing a method of manufacturing a silicon carbide semiconductor device according to a second embodiment; and

FIG. 17 is a flowchart showing a method of manufacturing a silicon carbide semiconductor device according to a third embodiment.

### DETAILED DESCRIPTION

With reference to the drawings, first to third embodiments of the present disclosure will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to third embodiments described below merely illustrate schematically devices and methods for specifying and giving shapes to the technical idea of the present disclosure, and the span of the technical idea is not limited to materials, shapes, structures, and relative positions of elements described herein.

As used in the present specification, a source region of a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOS transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

In addition, a crystal polymorphism is present in silicon carbide (SiC) crystals, and main examples include 3C of a cubic crystal, and 4H and 6H of a hexagonal crystal. A bandgap at room temperature is reported that is 2.23 eV in SiC of 3C-structure (3C-SiC), 3.26 eV in SiC having 4H-structure (4H-SiC), and 3.02 eV in SiC having 6H-structure (6H-SiC). The following embodiments are illustrated with a case of mainly using 4H-SiC and 3C-SiC.

### First Embodiment

### <Structure of Silicon Carbide Semiconductor Device>

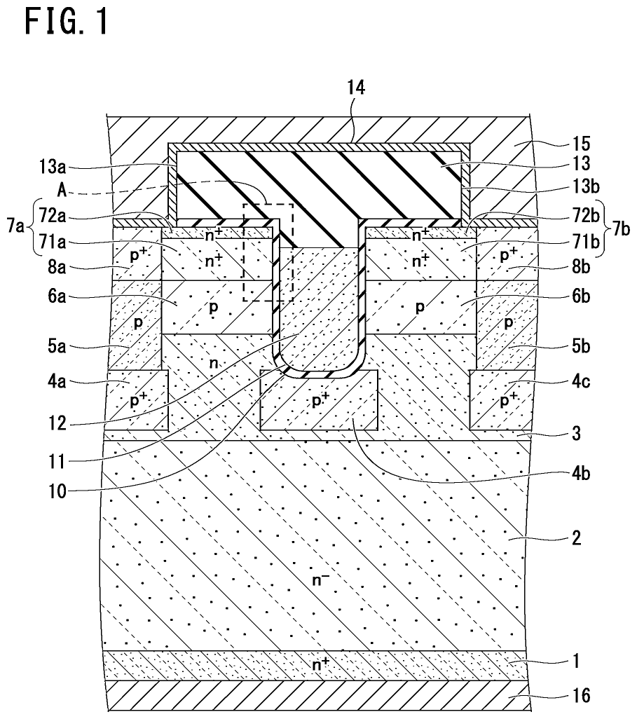

A silicon carbide semiconductor device according to a first embodiment is illustrated below with a case of including a trench-gate MOSFET as an active element, as illustrated in FIG. 1. While FIG. 1 illustrates a unit cell including an insulated gate electrode structure (11, 12) buried in a single trench 10, the semiconductor device actually includes the plural unit cells arranged repeatedly.

The silicon carbide semiconductor device according to the first embodiment includes a drift layer 2 of a first conductivity-type (n-type). The drift layer 2 is an epitaxially-grown layer including SiC such as 4H-SiC. The drift layer 2 has an impurity concentration in a range of about 1×10¹⁵ cm⁻³ or greater and 5×10¹⁶ cm⁻³ or less, for example. The drift layer 2 has a thickness in a range of about 1 micrometer or greater and 100 micrometers or smaller, for example. The impurity concentration and the thickness of the drift layer 2 can be adjusted as appropriate depending on breakdown-voltage specifications, for example.

A current spreading layer (CSL) 3 of the first conductivity-type (n-type) having a higher impurity concentration than the drift layer 2 is selectively provided on the top surface side of the drift layer 2. The bottom surface of the current spreading layer 3 is in contact with the top surface of the drift layer 2. The current spreading layer 3 is an epitaxially-grown layer including SiC such as 4H-SiC. The current spreading layer 3 has an impurity concentration in a range of about 5×10¹⁶ cm⁻³ or greater and 1×10¹⁸ cm⁻³ or less, for example. The current spreading layer 3 is not necessarily provided in this embodiment, and the drift layer 2 may be provided so as to extend toward a region corresponding to the current spreading layer 3 if not provided.

Base regions 6a and 6b of a second conductivity-type (p-type) are provided on the top surface side of the current spreading layer 3. The respective bottom surfaces of the base regions 6a and 6b are in contact with the top surface of the current spreading layer 3. When the current spreading layer 3 is not provided, the respective bottom surfaces of the base regions 6a and 6b are in contact with the top surface of the drift layer 2. The base regions 6a and 6b are each an epitaxially-grown layer including SiC such as 4H-SiC. The respective base regions 6a and 6b may be a region obtained such that p-type impurity ions are implanted into the current spreading layer 3. The respective base regions 6a and 6b have an impurity concentration in a range of about 1×10¹⁶ cm⁻³ or greater and 1×10¹⁸ cm⁻³ or less, for example.

First main regions (source regions) 7a and 7b of the first conductivity-type (n⁺-type) having a higher impurity concentration than the drift layer 2 are selectively provided on the top surface side of the base regions 6a and 6b. The source regions 7a and 7b are each a region including SiC obtained such that n-type impurity ions are implanted into the respective base regions 6a and 6b, for example.

The source region 7a has a two-layer structure that includes a source expansion part 71a of n⁺-type as a lower layer including a 4H-structure (4H-SiC), which is also referred to below as a “first region” or a “4H-SiC layer”, and a source contact part 72a of n⁺-type as an upper layer including a 3C-structure (3C-SiC), which is also referred to below as a “second region” or a “3C-SiC layer”. The bottom surface of the source expansion part 71a is in contact with the top surface of the base region 6a. The top surface of the source expansion part 71a is in contact with the bottom surface of the source contact part 72a. The source region 7b has a two-layer structure that includes a source expansion part 71b of n⁺-type as a lower layer including a 4H-structure (4H-SiC), which is also referred to below as a “first region” or a “4H-SiC layer”, and a source contact part 72b of n⁺-type as an upper layer including a 3C-structure (3C-SiC), which is also referred to below as a “second region” or a “3C-SiC layer”. The bottom surface of the source expansion part 71b is in contact with the top surface of the base region 6b. The top surface of the source expansion part 71b is in contact with the bottom surface of the source contact part 72b. The respective source regions 7a and 7b are described in more detail below.

The trench 10 is provided to penetrate the respective top surfaces of the source regions 7a and 7b to further penetrate the base regions 6a and 6b in the normal direction with respect to the top surfaces of the source regions 7a and 7b (in the depth direction). The bottom surface of the trench 10 reaches the current spreading layer 3. The trench 10 has a width of about one micrometer or smaller, for example. The side surface of the trench 10 on the left side is in contact with the source region 7a and the base region 6a. The side surface of the trench 10 on the right side is in contact with the source region 7b and the base region 6b. The trench 10 may have a stripe-like planar pattern extending in the backward direction and the frontward direction of the sheet of FIG. 1, or may have a dot-like planar pattern.

A gate insulating film 11 is provided along the bottom surface and the side surfaces of the trench 10. A gate electrode 12 is buried inside the trench 10 with the gate insulating film 11 interposed. The gate insulating film 11 and the gate electrode 12 implement the trench-gate insulated gate electrode structure (11, 12).

The gate insulating film 11 as used herein can be a single-layer film of a silicon oxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 12 can be made of a polysilicon layer (a doped polysilicon layer) heavily doped with either p-type or n-type impurity ions, or made of a layer including refractory metal such as titanium (Ti), tungsten (W), or nickel (Ni), for example.

A gate-bottom protection region 4b of the second conductivity-type (p⁺-type) is provided under the bottom of the trench 10 in the current spreading layer 3. The top surface of the gate-bottom protection region 4b is in contact with the bottom surface of the trench 10. The top surface of the gate-bottom protection region 4b is not necessarily in contact with the bottom surface of the trench 10. The gate-bottom protection region 4b has an impurity concentration in a range of about 1×10¹⁷ cm⁻³ or greater and 1×10¹⁹ cm⁻³ or less, for example.

The inside of the current spreading layer 3 is provided with first buried regions 4a and 4c of the second conductivity-type (p⁺-type) separately from the gate-bottom protection region 4b. The first buried regions 4a and 4c are positioned at substantially the same depth as the gate-bottom protection region 4b. The respective first buried regions 4a and 4c have an impurity concentration in a range of about 1×10¹⁷ cm⁻³ or greater and 1×10¹⁹ cm⁻³ or less, for example. The first buried regions 4a and 4c and the gate-bottom protection region 4b are each a region including SiC obtained such that p-type impurity ions are implanted into the current spreading layer 3. A p⁺-type connection part for connecting the respective first buried regions 4a and 4c and the gate-bottom protection region 4b may be selectively provided on the frontward side or the backward side of the sheet of FIG. 1.

Second buried regions 5a and 5b of the second conductivity-type (p-type) are provided on the top surface sides of the first buried regions 4a and 4c at the upper part of the current spreading layer 3. The second buried regions 5a and 5b electrically connect the first buried regions 4a and 4c with the base regions 6a and 6b. The respective bottom surfaces of the second buried regions 5a and 5b are in contact with the respective top surfaces of the first buried regions 4a and 4c. The side surfaces of the second buried regions 5a and 5b are in contact with the current spreading layer 3 and the base regions 6a and 6b. The second buried regions 5a and 5b are each a region including SiC obtained such that p-type impurity ions are implanted into the current spreading layer 3 and the base regions 6a and 6b, for example. The impurity concentration of the respective second buried region 5a and 5b may be substantially equal to, smaller than, or higher than that of the respective first buried regions 4a and 4c. The impurity concentration of the respective second buried regions 5a and 5b is in a range of about 1×10¹⁷ cm⁻³ or greater and 1×10¹⁹ cm⁻³ or less, for example.

Base contact regions 8a and 8b of p⁺-type having a higher impurity concentration than the second buried regions 5a and 5b are provided on the top surface sides of the second buried regions 5a and 5b. The base contact regions 8a and 8b are each a region including SiC obtained such that p-type impurity ions are implanted into the base regions 6a and 6b, for example. The respective base contact regions 8a and 8b have an impurity concentration in a range of about 5×10¹⁸ cm⁻³ or greater and 5×10²⁰ cm⁻³ or less, for example. The respective base contact regions 8a and 8b may include either 3C-SiC or 4H-SiC.

The bottom surface of the base contact region 8a is in contact with the top surface of the second buried region 5a, and the side surface of the base contact region 8a is in contact with the source expansion part 71a and the source contact part 72a of the source region 7a. The side surface of the base contact region 8a is not necessarily in contact with the source contact part 72a, and a part of the source expansion part 71a may be provided between the side surface of the base contact region 8a and the source contact part 72a, for example. The bottom surface of the base contact region 8b is in contact with the top surface of the second buried region 5b, and the side surface of the base contact region 8b is in contact with the source expansion part 71b and the source contact part 72b of the source region 7b. The side surface of the base contact region 8b is not necessarily in contact with the source contact part 72b, and a part of the source expansion part 71b may be provided between the side surface of the base contact region 8b and the source contact part 72b, for example.

The bottom surfaces of the base contact regions 8a and 8b are positioned at substantially the same depth as the bottom surfaces of the source expansion parts 71a and 71b of the source regions 7a and 7b, but may be either shallower or deeper than the bottom surfaces of the source expansion parts 71a and 71b of the source regions 7a and 7b instead. The respective top surfaces of the second buried regions 5a and 5b are not necessarily in contact with the respective bottom surfaces of the p⁺-type base contact regions 8a and 8b. For example, the base regions 6a and 6b may be interposed between the second buried regions 5a and 5b and the p⁺-type base contact regions 8a and 8b.

An interlayer insulating film 13 is provided on the top surface side of the gate electrode 12. The interlayer insulating film 13 is a single-layer film, such as a borophosphosilicate glass film (a BPSG film), a phosphosilicate glass film (a PSG film), a non-doped silicon oxide film without containing phosphorus (P) or boron (B) which is referred to as a non-doped silicate glass (NSG) film, a borosilicate glass film (a BSG film), or a silicon nitride (Si₃N₄) film, or a stacked-layer film including the above films stacked on one another. The interlayer insulating film 13 is provided with contact holes 13a and 13b to which the respective top surfaces of the source contact parts 72a and 72b and the base contact regions 8a and 8b are exposed.

A first main electrode (a source electrode) (14, 15) is provided to cover the interlayer insulating film 13 and the respective top surfaces of the source contact parts 72a and 72b and the base contact regions 8a and 8b exposed to the contact holes 13a and 13b of the interlayer insulating film 13. The source electrode (14, 15) includes a barrier metal layer 14 as a lower layer, and a source wiring electrode 15 as an upper layer. The barrier metal layer 14 includes titanium nitride (TiN), titanium (Ti), or metal having a stacked-layer structure of TiN/Ti in which Ti is a lower layer, for example. The barrier metal layer 14 is in direct contact with the source contact parts 72a and 72b and the base contact regions 8a and 8b so as to be in ohmic contact with each other at a low resistance.

The source wiring electrode 15 is electrically connected to the source regions 7a and 7b and the base contact regions 8a and 8b via the barrier metal layer 14. The source wiring electrode 15 is provided separately from a gate wiring electrode (not illustrated) electrically connected to the gate electrode 12. The source wiring electrode 15 includes metal such as aluminum (Al), copper (Cu), aluminum-silicon (Al—Si), aluminum-copper (Al—Cu), and aluminum-silicon-copper (Al—Si—Cu), for example.

A second main region (a drain region) 1 of the first conductivity-type (n⁺-type) having a higher impurity concentration than the drift layer 2 is provided on the bottom surface side of the drift layer 2. The drain region 1 is a semiconductor substrate (a SiC substrate) including 4H-SiC, for example. The drain region 1 has an impurity concentration in a range of about 1×10¹⁹ cm⁻³ or greater and 3×10²⁰ cm⁻³ or less, for example. The drain region 1 has a thickness in a range of about 30 micrometers or greater and 500 micrometers or smaller, for example. A dislocation conversion layer or a recombination promotion layer having a higher impurity concentration than the drift layer 2 and having a lower impurity concentration than the drain region 1 may be provided to serve as an n-type buffer layer between the drift layer 2 and the drain region 1.

A second main electrode (a drain electrode) 16 is provided on the bottom surface side of the drain region 1. The drain electrode 16 can be a single-layer film including gold (Au), or a metallic film including titanium (Ti), nickel (Ni), and Au stacked sequentially from the drain region 1, and may be further provided with a metallic film including molybdenum (Mo) or tungsten (W) on the lowermost side, for example. A drain contact layer such as a nickel silicide (NiSix) film for ensuring an ohmic contact may be provided between the drain region 1 and the drain electrode 16.

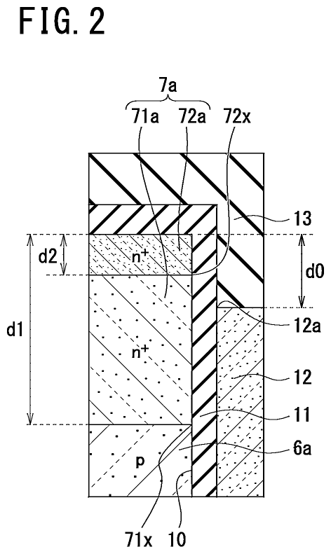

FIG. 2 is an enlarged cross-sectional view of region A indicated by the broken line including the source expansion part 71a and the source contact part 72a of the source region 7a, the gate insulating film 11, and the gate electrode 12 illustrated in FIG. 1. The structure regarding the source expansion part 71a and the source contact part 72a, and the positional relation between the gate electrode 12 and each of the source expansion part 71a and the source contact part 72a are described below with reference to FIG. 2.

The source expansion part 71a is a region having a smaller amount of crystal defects than the source contact part 72a while not taking over the crystal defects from the source contact part 72a. The source expansion part 71a mainly includes 4H-SiC. The proportion of 4H-SiC included in the source expansion part 71a is in a range of about 90% or higher and 100% or smaller. The source expansion part 71a may slightly include other structures such as an amorphous structure and 3C-SiC in addition to 4H-SiC. The crystal structures of the source expansion part 71a and the source contact part 72a can be measured (observed) such that a ratio of the areas of the crystal structures on the surfaces is obtained by use of a field-emission scanning electron microscope (FE-SEM) and electron backscatter diffraction (EBSD), for example.

A depth d1 from the top surface of the source contact part 72a to the bottom surface of the source expansion part 71a is in a range of about 200 nanometers or greater and 450 nanometers or smaller, for example. A thickness of the source expansion part 71a is in a range of about 150 nanometers or greater and 400 nanometers or smaller, for example. The source expansion part 71a has a lower impurity concentration than the source contact part 72a. The impurity concentration of the source expansion part 71a is in a range of about 1×10¹⁶/cm³ or greater and 1×10¹⁹/cm³ or less, for example. The source expansion part 71a includes phosphorus (P), nitrogen (N), or arsenic (As) as n-type impurities, for example. The source expansion part 71a may include argon (Ar) that is an inactive element on the top surface side when the source contact part 72a includes Ar.

The source contact part 72a is a region including 3C-SiC. The source contact part 72a may have a mixed-crystal structure of 3C-SiC and 4H-SiC. The source contact part 72a may further include other structures such as an amorphous structure and 4H-SiC in addition to 3C-SiC. The inclusion of 3C-SiC in the source contact part 72a can ensure an ohmic contact with the source electrode (14, 15) at a low resistance, since 3C-SiC has a narrower bandgap than 4H-SiC.

A proportion of 3C-SiC included in the source contact part 72a is in a range of about 10% or higher and 100% or smaller, and may be in a range of about 70% or higher and 100% or smaller, or in a range of about 85% or higher and 100% or smaller, for example, at least on the top surface side of the source contact part 72a. To ensure a good ohmic contact with the source electrode (14, 15), the proportion of 3C-SiC included in the source contact part 72a is preferably 70% or higher, and more preferably 85% or higher.

A depth d2 from the top surface to the bottom surface of the source contact part 72a (a thickness of the source contact part 72a) is in a range of about 30 nanometers or greater and 100 nanometers or smaller, for example. The source contact part 72a has a higher impurity concentration than the source expansion part 71a. The impurity concentration of the source contact part 72a is in a range of about 1×10¹⁸/cm³ or greater and 5×10¹⁹/cm³ or less, for example. The source contact part 72a includes n-type impurities common to those included in the source expansion part 71a, such as phosphorus (P), nitrogen (N), or arsenic (As). The source contact part 72a may include argon (Ar) that is an inactive element, in addition to the n-type impurities.

The respective crystal structures of the source expansion part 71a and the source contact part 72a can be formed independently of each other such that some conditions, such as the element to be implanted, the temperature during the ion implantation, the dose of the impurity ions (the impurity concentration), and the activation temperature, are changed for each of the source expansion part 71a and the source contact part 72a.

The source expansion part 71a in the silicon carbide semiconductor device according to the first embodiment can be formed such that n-type impurity ions are implanted to 4H-SiC at a room temperature and at an impurity concentration sufficient to avoid breakage of structure of 4H-SiC so as to keep 4H-SiC.

The source contact part 72a in the silicon carbide semiconductor device according to the first embodiment is formed such that argon (Ar) that is inert gas, or silicon (Si) or carbon (C) that is an element of Group 4 is implanted to 4H-SiC, instead of the n-type impurities, at a room temperature so as to break 4H-SiC to form an amorphous structure by use of damage during the ion implantation. Thereafter, activation annealing is executed to lead the amorphous structure when recrystallized to turn to 3C-SiC, so as to form the source contact part 72a including 3C-SiC,

As illustrated in FIG. 2, the end of the top surface (the upper end) 12a of the gate electrode 12 in contact with the gate insulating film 11 is located at a position deeper than the bottom surface (the lower end) 72x of the source contact part 72a in contact with the gate insulating film 11 and shallower than the bottom surface (the lower end) 71x of the source expansion part 71a in contact with the gate insulating film 11. Alternatively, the source contact part 72a and the gate insulating film 11 may be separated from each other so that a part of the source expansion part 71a is interposed between the source contact part 72a and the gate insulating film 11. In such a case, the end of the top surface (the upper end) 12a of the gate electrode 12 in contact with the gate insulating film 11 may be shallower than the bottom surface (the lower end) 72x of the source contact part 72a toward the gate insulating film 11.

The top surface 12a of the gate electrode 12 at the position in contact with the gate insulating film 11 may be the uppermost surface of the gate electrode 12. For example, when the entire top surface of the gate electrode 12 is curved downward, the top surface in the middle of the gate electrode 12 may be located at a position deeper than the top surface 12a at the end part of the gate electrode 12.

The gate electrode 12 is opposed to the source expansion part 71a with the gate insulating film 11 interposed, while the gate electrode 12 and the source contact part 72a are not opposed to each other. The source contact part 72a is opposed to the interlayer insulating film 13 with the gate insulating film 11 interposed. A drop amount do of the gate electrode 12 from the top surface of the source contact part 72a is in a range of about 100 nanometers or greater and 300 nanometers or smaller, for example. The drop amount do of the gate electrode 12 and the position of the top surface 12a of the gate electrode 12 in contact with the gate insulating film 11 can be controlled such that the etching conditions applied for the gate electrode 12 are adjusted, for example.

The source expansion part 71b and the source contact part 72b of the source region 7b illustrated in FIG. 1 have the configurations common to those of the source expansion part 71a and the source contact part 72a of the source region 7a, and overlapping explanations are not repeated below. The positional relation between the gate electrode 12 and each of the source expansion part 71b and the source contact part 72b of the source region 7b is also common to that between the gate electrode 12 and each of the source expansion part 71a and the source contact part 72a of the source region 7a, and overlapping explanations are not repeated below.

The silicon carbide semiconductor device according to the first embodiment during the switching operation causes an inversion layer (a channel) to be formed in the respective base regions 6a and 6b toward the side surfaces of the trench 10 so as to be in the ON-state when a positive voltage is applied to the drain electrode 16 and a positive voltage of a threshold or greater is applied to the gate electrode 12 with the source electrode (14, 15) used as a ground potential. In the ON-state, a current flows from the drain electrode 16 toward the source electrode (14, 15) through the drain region 1, the drift layer 2, the current spreading layer 3, the respective inversion layers of the base regions 6a and 6b, and the source regions 7a and 7b. When the voltage applied to the gate electrode 12 is smaller than the threshold, the silicon carbide semiconductor device is led to be in the OFF-state since no inversion layer is formed in the respective base regions 6a and 6b, while no current flows from the drain electrode 16 toward the source electrode (14, 15).

The configuration of the silicon carbide semiconductor device according to the first embodiment, in which the source region 7a has the two-layer structure including the source expansion part 71a and the source contact part 72a, and the source expansion part 71a of the upper layer in contact with the source electrode (14, 15) includes 3C-SiC, can ensure the ohmic contact between the source contact part 72a and the source electrode (14, 15) at a low resistance without a silicide layer including nickel (Ni) silicide or the like provided. This configuration thus can eliminate a problem of separation of such a silicide layer when not provided.

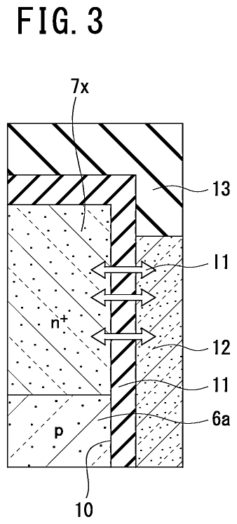

If, as illustrated in FIG. 3, a source region 7x including 3C-SiC has a single-layer structure so that the source region 7x is opposed to the gate electrode 12 with the gate insulating film 11 interposed, the source region 7x including 3C-SiC could be in ohmic contact with the source electrode (14, 15), but a problem of a leakage current I1 between the gate electrode 12 and the source region 7x would be caused, since 3C-SiC has a larger amount of crystal defects and greater surface roughness than 4H-SiC.

In contrast, the silicon carbide semiconductor device according to the first embodiment has the configuration in which the top surface 12a of the gate electrode 12 is located at a position deeper than the bottom surface 72x of the source contact part 72a and shallower than the bottom surface 71x of the source expansion part 71a, as illustrated in FIG. 2. This configuration leads the source expansion part 71a of the source region 7a having a relatively small amount of crystal defects to be opposed to the gate electrode 12 with the gate insulating film 11 interposed, while the source contact part 72a of the source region 7a having a relatively large amount of crystal defects is not opposed to the gate electrode 12, so as to suppress a leakage current between the source region 7a and the gate electrode 12.

### <Method of Manufacturing Silicon Carbide Semiconductor Device>

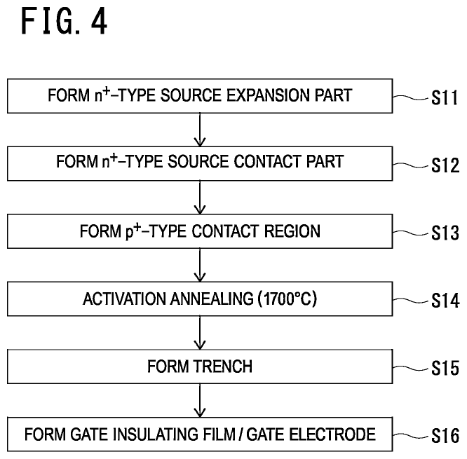

An example of a method of manufacturing the silicon carbide semiconductor device according to the first embodiment is described below. It should be understood that the method of manufacturing the silicon carbide semiconductor device described below is an example, and the silicon carbide semiconductor device can be manufactured by other methods including modified examples of this embodiment within the scope of the appended claims. FIG. 4 is a flowchart showing a part of a procedure of the method of manufacturing the silicon carbide semiconductor device according to the first embodiment. The following explanations are made with reference to FIG. 4 as necessarily.

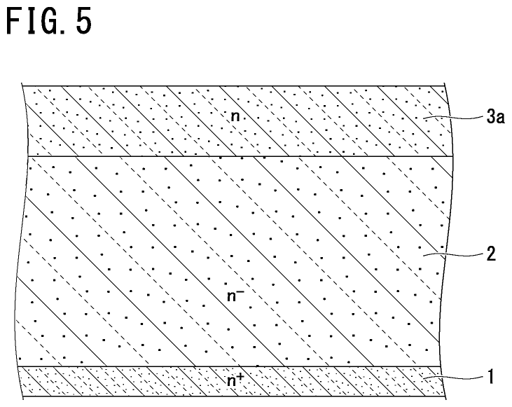

First, the semiconductor substrate (the SiC substrate) 1 of n⁺-type (refer to FIG. 1) including 4H-SiC doped with n-type impurities such as nitrogen (N) is prepared. The top surface of the SiC substrate 1 has an off-angle of about three degrees or greater and eight degrees or smaller with respect to a {0001}-plane, for example. Next, the drift layer 2 of n-type (refer to FIG. 1) including 4H-SiC doped with n-type impurities such as N and having a lower impurity concentration than the SiC substrate 1 is epitaxially grown on the top surface of the SiC substrate 1. Next, as illustrated in FIG. 5, an n-type layer 3a including 4H-SiC doped with n-type impurities such as N and having a higher impurity concentration than the drift layer 2 is epitaxially grown on the top surface of the drift layer 2. Alternatively, the n-type layer 3a may be formed by implantation of n-type impurity ions such as nitrogen (N) to the upper part of the drift layer 2.

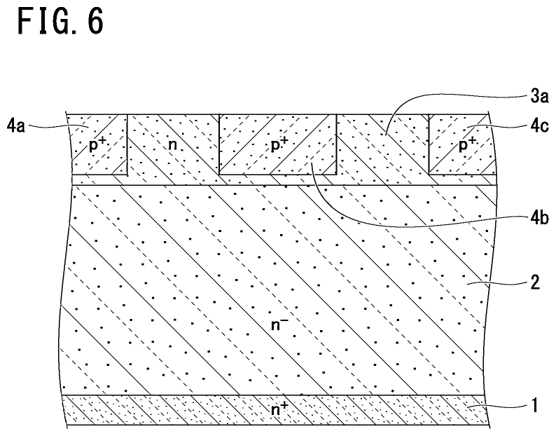

Next, an oxide film is deposited on the top surface of the n-type layer 3a by chemical vapor deposition (CVD), for example. A photoresist film is then applied to the top surface of the oxide film, and the oxide film is delineated by photolithography and dry etching, for example. Using the delineated oxide film as a mask for ion implantation, p-type impurity ions such as aluminum (Al) are selectively implanted. Instead of the oxide film, the photoresist film may be used as the mask for ion implantation. The oxide film used as the mask for ion implantation is then removed. This step provides the p⁺-type first buried regions 4a and 4c and the p⁺-type gate-bottom protection region 4b selectively at the upper part of the n-type layer 3a, as illustrated in FIG. 6.

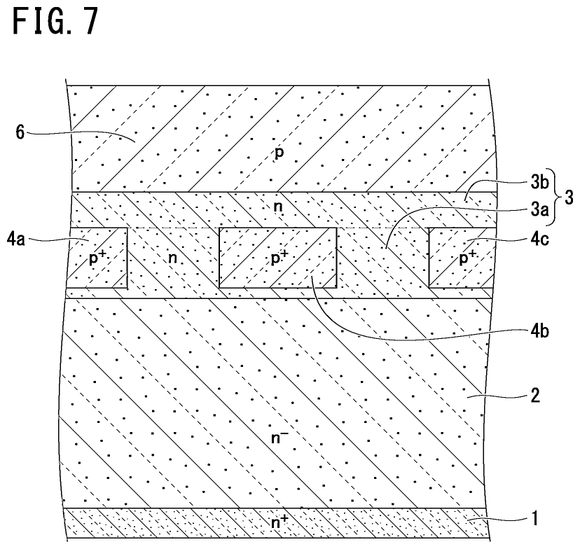

Next, an n-type layer 3b (refer to FIG. 7) including n-type 4H-SiC is epitaxially grown on the respective top surfaces of the n-type layer 3a, the first buried regions 4a and 4c, and the gate-bottom protection region 4b. This step provides the current spreading layer 3 including the n-type layer 3a and the n-type layer 3b. Next, as illustrated in FIG. 7, a base region 6 including p-type 4H-SiC is epitaxially grown on the top surface of the current spreading layer 3. The n-type layer 3b and the base region 6 may be formed by ion implantation, instead of the epitaxial grown.

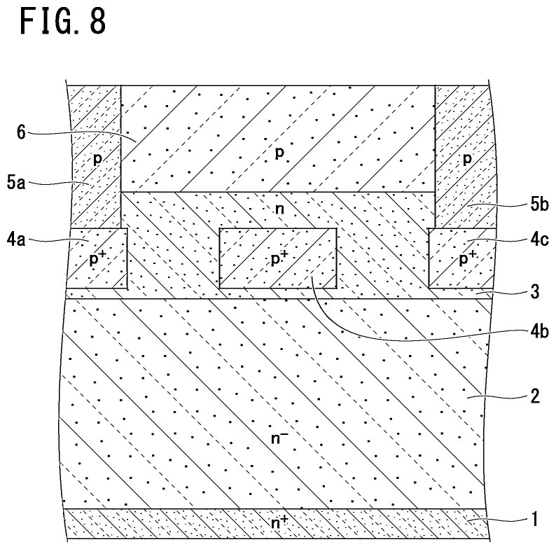

Next, an oxide film is deposited on the top surface of the base region 6 by CVD, for example. A photoresist film is then applied to the top surface of the oxide film, and the oxide film is delineated by photolithography and dry etching, for example. Using the delineated oxide film as a mask for ion implantation, p-type impurity ions such as aluminum (Al) are selectively implanted. Instead of the oxide film, the photoresist film may be used as the mask for ion implantation. The oxide film used as the mask for ion implantation is then removed. This step provides the p-type second buried regions 5a and 5b selectively on the top surface sides of the first buried region 4a and 4c, as illustrated in FIG. 8.

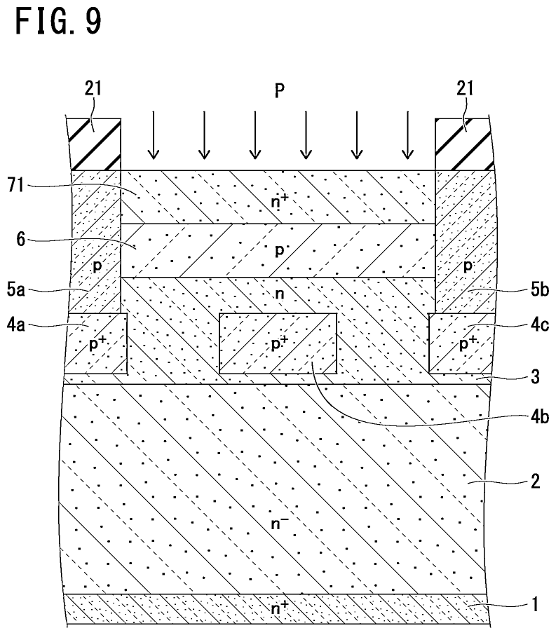

Next, an n⁺-type-source-expansion-part forming step in step S11 shown in FIG. 4 is executed. The n⁺-type-source-expansion-part forming step deposits an oxide film 21 (refer to FIG. 9) on the top surface of the base region 6 by CVD, for example. A photoresist film is then applied to the top surface of the oxide film 21, and the oxide film 21 is delineated by photolithography and dry etching, for example. Using the delineated oxide film 21 as a mask for ion implantation, n-type impurity ions such as phosphorus (P), nitrogen (N), or arsenic (As) are implanted under the condition of room temperature (RT) with no heat applied, as illustrated in FIG. 9. The room temperature as used herein is in a range of about 1° C. or higher and 40° C. or lower, and may be in a range of about 15° C. or higher and 30° C. or lower, for example. Instead of the oxide film 21, the photoresist film may be used as the mask for ion implantation. This step provides the n⁺-type source expansion part 71 at the upper part of the base region 6.

Upon the ion implantation for the source expansion part 71, phosphorus (P: atomic number 15) having a relatively small atomic weight is preferably used, and nitrogen (N: atomic number 7) having a smaller atomic weight is more preferably used as the n-type impurities, instead of arsenic (As: atomic number 33) having a relatively large atomic weight, in order to have less damage than in the ion implantation for the source contact part 72 described below.

The ion implantation for forming the source expansion part 71 may include a single stage. An acceleration energy upon the ion implantation of P at the single stage may be in a range of about 100 keV or higher and 140 keV or smaller, and preferably in a range of about 110 keV or higher and 130 keV or smaller. The dose of the impurity ions upon the single-state ion implantation is in a range of about 1×10¹³/cm² or greater and 5×10¹³/cm² or less, and more preferably in a range of about 3×10¹³/cm² or greater and 5×10¹³/cm² or less, for example.

The ion implantation for forming the source expansion part 71 may include two or more of (multiple) stages. For example, n-type impurity ions such as P, N, or As are implanted as a first ion implantation step at a room temperature with no heat applied. Next, n-type impurity ions such as P, N, or As are implanted as a second ion implantation step at smaller acceleration energy with a smaller dose than in the first ion implantation step at a room temperature with no heat applied. The first ion implantation step and the second ion implantation step may use either the same n-type impurity ions or different n-type impurity ions. Alternatively, the order of the first ion implantation step and the second ion implantation step may be exchanged so as to execute the second ion implantation step first, followed by the first ion implantation step.

The acceleration energy upon the first ion implantation step may be in a range of about 150 keV or higher and 250 keV or smaller, and more preferably in a range of about 180 keV or higher and 220 keV or smaller, for example. The dose upon the first ion implantation step may be in a range of about 1×10¹³/cm² or greater and 5×10¹³/cm² or less, and more preferably in a range of about 2×10¹³/cm² or greater and 4×10¹³/cm² or less, for example.

The acceleration energy upon the second ion implantation step may be in a range of about 50 keV or higher and 120 keV or smaller, and more preferably in a range of about 60 keV or higher and 100 keV or smaller, for example. The dose upon the second ion implantation step may be in a range of about 1×10¹³/cm² or greater and 5×10¹³/cm² or less, and more preferably in a range of about 2×10¹³/cm² or greater and 4×10¹³/cm² or less, for example.

The execution of the ion implantation for forming the source expansion part 71 at two or more (multiple) stages can increase a surface concentration of the source contact part 72 and reduce a contact resistance, as compared with the ion implantation for forming the source expansion part 71 at the single stage. Instead, the execution of the ion implantation for forming the source expansion part 71 at the single stage can reduce manufacturing costs, as compared with the ion implantation for forming the source expansion part 71 at two or more (multiple) stages.

The implantation of the n-type impurity ions for forming the source expansion part 71 can lead the impurity concentration to a range of about 1×10¹⁷ cm⁻³ or greater and 1×10¹⁹ cm⁻³ or less so as to provide a current path at a depth in a range of 350 nanometers or greater and 400 nanometers or less from the top surface of the source expansion part 71, for example.

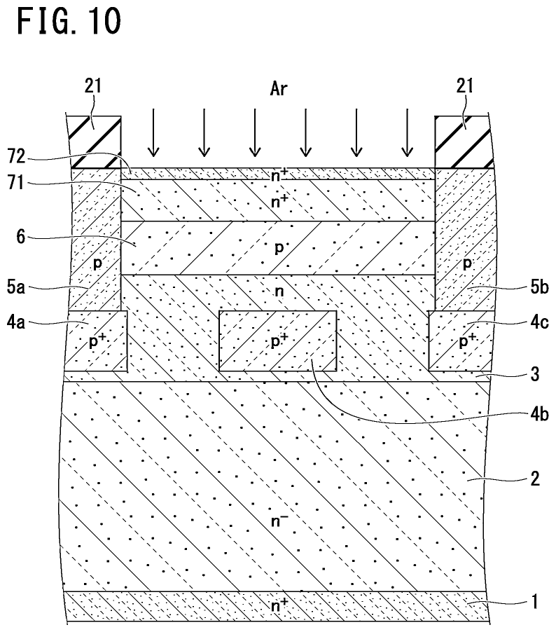

Next, an n⁺-type-source-contact-part forming step in step S12 shown in FIG. 4 is executed. The n⁺-type-source-contact-part forming step implants not the n-type impurity ions but impurity ions of at least any of Ar, Si, or C at a room temperature with no heat applied, while using the oxide film 21 described above continuously as a mask for ion implantation, as illustrated in FIG. 10. The room temperature as used herein is in a range of about 1° C. or higher and 40° C. or lower, and may be in a range of about 15° C. or higher and 30° C. or lower, for example. The room temperature during the ion implantation may be either the same as or different from the room temperature during the ion implantation for forming the source expansion part 71. Instead of the oxide film 21, the photoresist film may be used as the mask for ion implantation. This step provides the n⁺-type source contact part 72 on the top surface side of the source expansion part 71.

The execution of the ion implantation for forming the source contact part 72 breaks the structure of 4H-SiC on the top surface side of the source expansion part 71 so as to provide the amorphous structure. The ion implantation preferably uses Si (atomic number 14) having a relatively large atomic weight, and more preferably uses Ar (atomic number 18) having a larger atomic weight, instead of C (atomic number 6) having a relatively small atomic weight, in order to have greater damage than in the ion implantation for the source expansion part 71 described above.

The acceleration energy upon the ion implantation for forming the source contact part 72 in the case of implanting Ar may be in a range of about 50 keV or higher and 100 keV or smaller, and preferably in a range of about 60 keV or higher and 80 keV or smaller. The acceleration energy in the case of implanting Si may be in a range of about 60 keV or higher and 120 keV or smaller, and preferably in a range of about 70 keV or higher and 100 keV or smaller. The acceleration energy in the case of implanting C may be in a range of about 20 keV or higher and 60 keV or smaller, and preferably in a range of about 25 keV or higher and 40 keV or smaller.

The dose of the impurity ions implanted for forming the source contact part 72 in the case of implanting Ar may be in a range of about 2×10¹⁴/cm² or greater and 2×10¹⁵/cm² or less, and preferably in a range of about 2×10¹⁴/cm² or greater and 1×10¹⁵/cm² or less. The dose of the impurity ions in the case of implanting Si may be in a range of about 2×10¹⁴/cm² or greater and 2×10¹⁶/cm² or less, and preferably in a range of about 2×10¹⁴/cm² or greater and 1×10¹⁵/cm² or less. The dose of the impurity ions in the case of implanting C may be in a range of about 1×10¹⁵/cm² or greater and 5×10¹⁵/cm² or less, and preferably in a range of about 1×10¹⁵/cm² or greater and 3×10¹⁵/cm² or less. The higher dose of the impurity ions to be implanted can increase the ratio of 3C included in the source contact part 72.

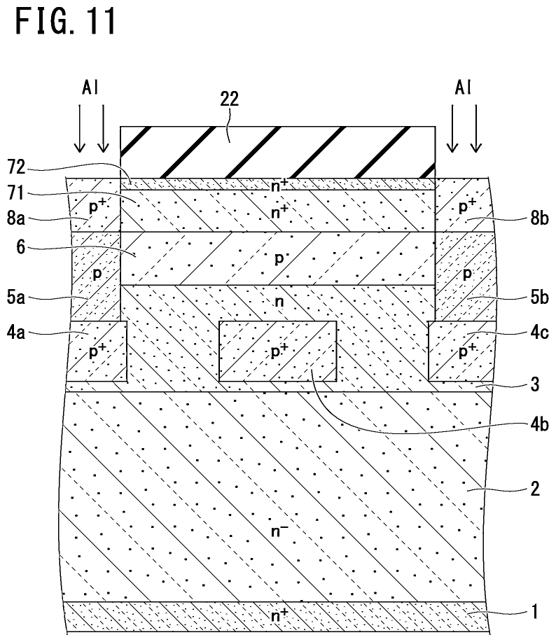

Next, a p⁺-type-contact-region forming step in step S13 shown in FIG. 4 is executed. The p⁺-type-contact-region forming step deposits an oxide film 22 on the top surface of the base region 6 by CVD or the like. A photoresist film is then applied to the top surface of the oxide film 22, and the oxide film 22 is delineated by photolithography and dry etching. Using the delineated oxide film 22 as a mask for ion implantation, p-type impurity ions such as aluminum (Al) and boron (B) are implanted, as illustrated in FIG. 11. Instead of the oxide film 22, the photoresist film may be used as the mask for ion implantation. This step selectively forms the p⁺-type base contact regions 8a and 8b on the top surface side of the second buried regions 5a and 5b. The oxide film 22 used as the mask for ion implantation is then removed.

The order of executing the ion implantation for forming the base region 6, the ion implantation for forming the source expansion part 71, the ion implantation for forming the source contact part 72, the ion implantation for forming the second buried regions 5a and 5b, and the ion implantation for forming the base contact regions 8a and 8b is not limited to the case described above, and may be changed as appropriate.

Next, an activation annealing (heat treatment) step in step S14 shown in FIG. 4 is executed. This activation annealing is executed at a temperature in a range of about 1600° C. or higher and 1900° C. or lower, so as to collectively activate the p-type impurity ions or the n-type impurity ions implanted into the regions such as the first buried regions 4a and 4c, the gate-bottom protection region 4b, the second buried regions 5a and 5b, the source expansion part 71, the source contact part 72, and the base contact regions 8a and 8b. At this point, the amorphous structure in the source contact part 72 is recrystallized to turn to 3C-SiC, so as to form the source contact part 72 including 3C-SiC.

While the present embodiment is illustrated with the case in which the single activation annealing is collectively executed after all of the ion implantation steps are finished, the activation annealing may be executed several times independently after each of the ion implantation steps is executed. Alternatively, the present embodiment may include a process of forming a cap film including carbon (C), executing the activation annealing with the cap film formed, and then removing the cap film after the activation annealing.

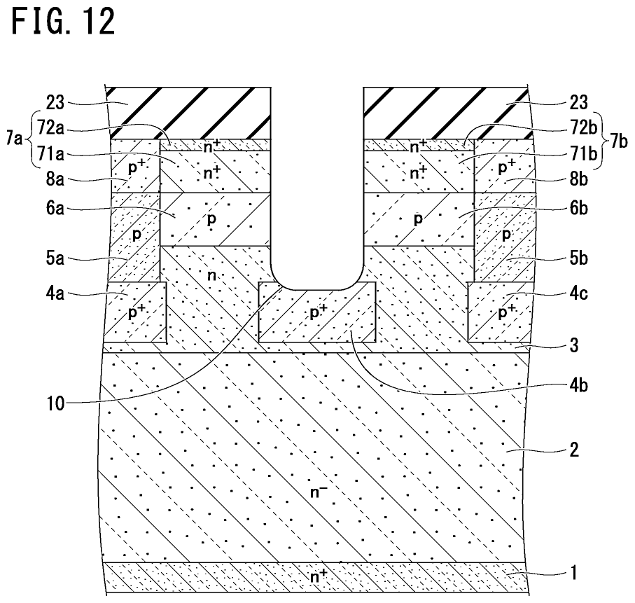

Next, a trench forming step in step S15 shown in FIG. 4 is executed. The trench forming step deposits an oxide film 23 (refer to FIG. 12) on the respective top surfaces of the base contact regions 8a and 8b and the source contact part 72 by CVD or the like. A photoresist film is then applied to the top surface of the oxide film 23, and the oxide film 23 is delineated by photolithography and dry etching. Using the delineated oxide film 23 as a mask for etching, the trench 10 is selectively dug from the top surface of the source contact part 72 in the depth direction by dry etching such as reactive ion etching (RIE), as illustrated in FIG. 12. Instead of the oxide film 23, the photoresist film may be used as the mask for etching.

The trench 10 penetrates the source expansion part 71, the source contact part 72, and the base region 6 so as to dug the upper part of the current spreading layer 3 to reach the gate-bottom protection region 4b. The source expansion part 71 is divided into the source expansion parts 71a and 71b, the source contact part 72 is divided into the source contact parts 72a and 72b, and the base region 6 is divided into the base regions 6a and 6b. The source expansion parts 71a and 71b and the source contact parts 72a and 72b implement the source regions 7a and 7b. The oxide film 23 used as the mask for etching is then removed. The trench 10, when reaching the current spreading layer 3, does not need to reach the gate-bottom protection region 4b.

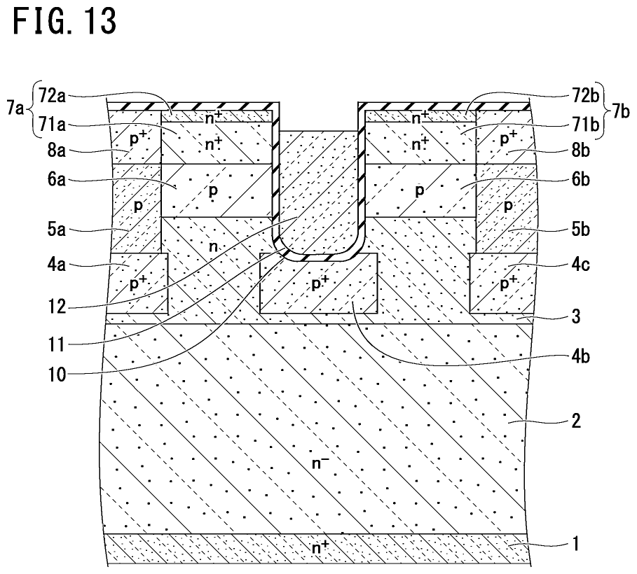

Next, a gate-insulating-film/gate-electrode forming step in step S16 shown in FIG. 4 is executed. The gate-insulating-film/gate-electrode forming step forms the gate insulating film 11 (refer to FIG. 13) on the bottom surface and the side surfaces of the trench 10 and on the respective top surfaces of the source contact parts 72a and 72b and the base contact regions 8a and 8b by a method such as CVD, high temperature oxidation (HTO), or thermal oxidation. Upon the formation of the gate insulating film 11, annealing that is post deposition annealing (PDA) is executed at a temperature in a range of about 900° C. or higher and 1350° C. or lower, for example.

Next, a polysilicon layer (a doped polysilicon layer) heavily doped with impurities such as phosphorus (P) or boron (B) is deposited so as to fill the inside of the trench 10 by CVD or the like. A part of the polysilicon layer is then selectively removed by photolithography and dry etching. This step provides the insulated gate electrode structure (11, 12) implemented by the gate insulating film 11 and the gate electrode 12, as illustrated in FIG. 13. At this point, as illustrated in FIG. 2, the drop amount do of the gate electrode 12 is adjusted such that the top surface 12a of the gate electrode 12 at the position in contact with the gate insulating film 11 is located to be deeper than the bottom surface (the lower end) 72x of the source contact part 72a and shallower than the bottom surface (the lower end) 71x of the source expansion part 71a.

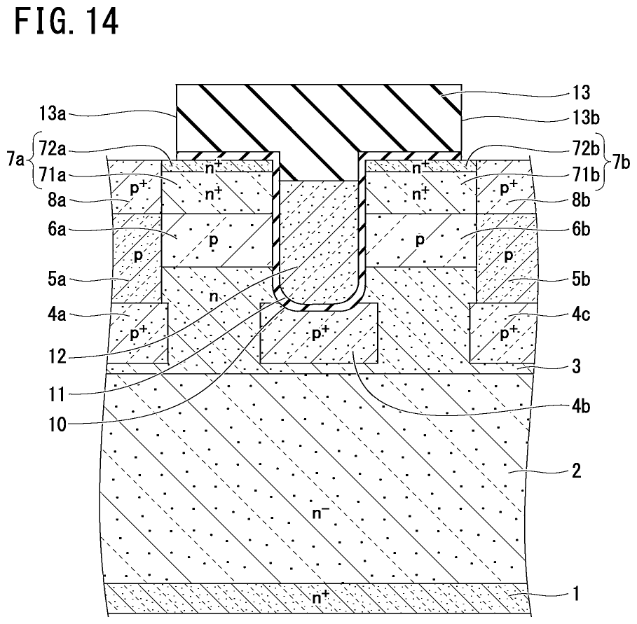

Next, the interlayer insulating film 13 (refer to FIG. 14) is deposited on the top surface of the insulated gate electrode structure (11, 12) by CVD or the like. A part of the interlayer insulating film 13 and a part of the gate insulating film 11 are then selectively removed by photolithography and dry etching so as to open the contact holes 13a and 13b in the interlayer insulating film 13 to which the respective top surfaces of the source contact parts 72a and 72b and the base contact regions 8a and 8b are exposed, as illustrated in FIG. 14. This step may be followed by annealing (reflowing) for flattening the interlayer insulating film 13.

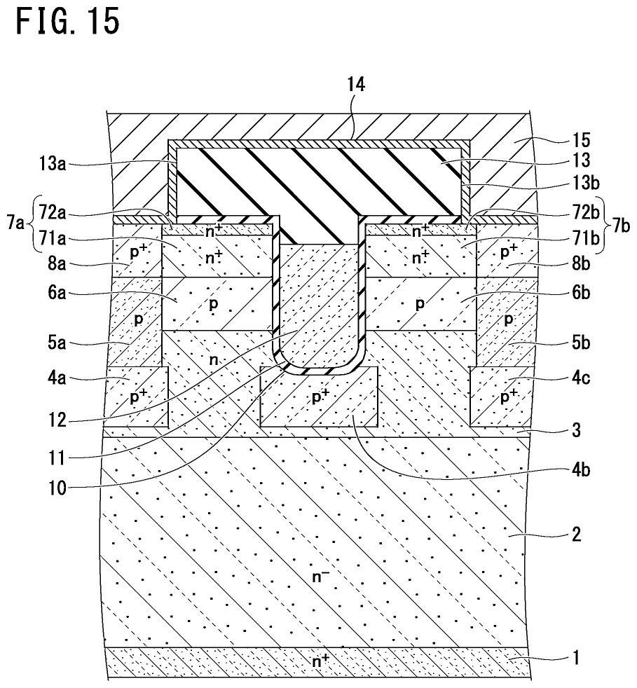

Next, the barrier metal layer 14 and the source wiring electrode 15 are sequentially formed to cover the top surface and the side surfaces of the interlayer insulating film 13 and the respective top surfaces of the source contact parts 72a and 72b and the base contact regions 8a and 8b by sputtering or vapor deposition, for example, so as to provide the source electrode (14, 15), as illustrated in FIG. 15. The barrier metal layer 14 is in ohmic contact with the source contact parts 72a and 72b of the source regions 7a and 7b and the base contact regions 8a and 8b at a low resistance.

Next, the SiC substrate 1 is ground from the bottom surface side by grinding or chemical mechanical polishing (CMP) or the like to adjust the thickness so as to obtain the drain region 1. Thereafter, the drain electrode 16 (refer to FIG. 1) including gold (Au) is formed on the entire bottom surface of the drain region 1 by sputtering or vapor deposition, for example. The silicon carbide semiconductor device illustrated in FIG. 1 is thus completed.

The method of manufacturing the silicon carbide semiconductor device according to the first embodiment, which has the configuration in which the source region 7a has the two-layer structure including the source expansion part 71a of 4H-SiC and the source contact part 72a of 3C-SiC, and the source region 7b has the two-layer structure including the source expansion part 71b of 4H-SiC and the source contact part 72b of 3C-SiC, can provide the trench-gate silicon carbide semiconductor device that can lead the respective source contact parts 72a and 72b to be in ohmic contact with the source electrode (14, 15) at a low resistance without the formation of any silicide layer including nickel (Ni) silicide.

Further, the silicon carbide semiconductor device according to the first embodiment has the configuration in which the top surface 12a of the gate electrode 12 is located at a position deeper than the bottom surface 72x of the source contact part 72a and shallower than the bottom surface 71x of the source expansion part 71a. This configuration leads the source expansion part 71a of the source region 7a having a relatively small amount of crystal defects to be opposed to the gate electrode 12 with the gate insulating film 11 interposed, while the source contact part 72a of the source region 7a having a relatively large amount of crystal defects is not opposed to the gate electrode 12, so as to suppress a leakage current between the source region 7a and the gate electrode 12.

Further, the method of manufacturing the silicon carbide semiconductor device according to the first embodiment implants not the n-type impurity ions but Si, C, or Ar at a room temperature upon the ion implantation for forming the source contact part 72. This method can decrease the dose of the n-type impurity ions upon the ion implantation for forming the source expansion part 71 and the source contact part 72, so as to avoid crystal effects caused when the crystal structure is led to turn to 3C, and suppress a drain-source leakage current. The decrease of the dose of the n-type impurity ions described above can further eliminate a heating step upon the implantation of the n-type impurity ions for forming the source expansion part 71, so as to enable the implantation of the n-type impurity ions at a room temperature. This method thus can achieve a reduction in manufacturing cost more than a case in which the implantation of the n-type impurity ions for forming the source expansion part 71 is executed at a high temperature, such as about 200° C. or higher and 600° C. or lower.

Further, the method of manufacturing the silicon carbide semiconductor device according to the first embodiment implants the impurity ions of Si or C when forming the source contact part 72, so as to facilitate the recovery of the crystal structure by heating and thus decrease the drain-source leakage current to a lower level than the case of implanting the impurity ions of Ar. The allowable dose of Si or C to be implanted, when an upper limit is set to the leakage current, is greater than the dose of Ar. The increase of the dose of Si or C thus can increase the proportion of 3C to be formed and further decrease the contact resistance. This method can also set the impurity concentration on the surface side of the source contact part 72 to a lower level, so as to facilitate the decrease in the implantation steps.

Further, the method of manufacturing the silicon carbide semiconductor device according to the first embodiment, which implants the impurity ions of Ar when forming the source contact part 72, can facilitate the introduction of damage, so as to decrease the dose of the impurity ions since the atomic weight of Ar is small.

Next, first to sixth examples and a comparative example are described below with reference to table 1.

TABLE 1

| | | | ACCELERATION | | PROPORTION | LEAKAGE |
|---|---|---|---|---|---|---|
| | | ION | ENERGY | DOSE | OF 3 C | CURRENT |
| | TEMPERATURE | SPECIES | [keV] | [cm⁻²] | [%] | [A] |
| FIRST | ROOM | P⁺ | 200 | 4 × 10¹³ | 70 | 5 × 10⁻⁶ |
| EXAMPLE | TEMPERATURE | | | | | |
| | ROOM | P⁺ | 85 | 3 × 10¹³ | | |
| | TEMPERATURE | | | | | |
| | ROOM | Ar⁺ | 70 | 2 × 10¹⁴ | | |
| | TEMPERATURE | | | | | |
| SECOND | ROOM | P⁺ | 200 | 4 × 10¹³ | 85 | — |
| EXAMPLE | TEMPERATURE | | | | | |
| | ROOM | P⁺ | 85 | 3 × 10¹³ | | |
| | TEMPERATURE | | | | | |
| | ROOM | Ar⁺ | 70 | 1 × 10¹⁵ | | |
| | TEMPERATURE | | | | | |
| THIRD | ROOM | P⁺ | 200 | 4 × 10¹³ | 70 | — |
| EXAMPLE | TEMPERATURE | | | | | |
| | ROOM | P⁺ | 85 | 3 × 10¹³ | | |
| | TEMPERATURE | | | | | |
| | ROOM | Si⁺ | 70 | 2 × 10¹⁴ | | |
| | TEMPERATURE | | | | | |
| FOURTH | ROOM | P⁺ | 200 | 4 × 10¹³ | 85 | — |
| EXAMPLE | TEMPERATURE | | | | | |
| | ROOM | P⁺ | 85 | 3 × 10¹³ | | |
| | TEMPERATURE | | | | | |
| | ROOM | Si⁺ | 70 | 1 × 10¹⁵ | | |
| | TEMPERATURE | | | | | |
| FIFTH | ROOM | P⁺ | 200 | 4 × 10¹³ | 70 | — |
| EXAMPLE | TEMPERATURE | | | | | |
| | ROOM | P⁺ | 85 | 3 × 10¹³ | | |
| | TEMPERATURE | | | | | |
| | ROOM | C⁺ | 70 | 1 × 10¹⁵ | | |
| | TEMPERATURE | | | | | |
| SIXTH | ROOM | P⁺ | 200 | 4 × 10¹³ | 85 | — |
| EXAMPLE | TEMPERATURE | | | | | |
| | ROOM | P⁺ | 85 | 3 × 10¹³ | | |
| | TEMPERATURE | | | | | |
| | ROOM | C⁺ | 70 | 3 × 10¹⁵ | | |
| | TEMPERATURE | | | | | |
| COMPARATIVE | ROOM | P⁺ | 200 | 4 × 10¹³ | — | 1 × 10⁻⁵ |
| EXAMPLE | TEMPERATURE | | | | | |
| | ROOM | P⁺ | 85 | 3 × 10¹³ | | |
| | TEMPERATURE | | | | | |
| | ROOM | P⁺ | 70 | 2 × 10¹⁴ | | |
| | TEMPERATURE | | | | | |

### First Example

The first example executed a two-stage ion implantation including a first ion implantation of P⁺ implanted at a room temperature and acceleration energy of 200 keV with a dose of 4×10¹³ cm⁻², and a second ion implantation of P⁺ implanted at a room temperature and acceleration energy of 85 keV with a dose of 3×10¹³ cm⁻². Thereafter, impurity ions of Art were implanted at a room temperature and acceleration energy of 70 keV with a dose of 2×10¹⁴ cm⁻², so as to manufacture a silicon carbide semiconductor device having a breakdown voltage of 1200 volts.

The first example had a result that the silicon carbide semiconductor device had a proportion of 3C that was 70% obtained such that a SiC surface was analyzed by EBSD to calculate the proportion of the crystal phase. Evaluation revealed that the silicon carbide semiconductor device of the first example had a drain-source leakage current (Idss) that was 5×10⁻⁶ A.

### Second Example

The second example executed a two-stage ion implantation including a first ion implantation of P⁺ implanted at a room temperature and acceleration energy of 200 keV with a dose of 4×10¹³ cm⁻², and a second ion implantation of P⁺ implanted at a room temperature and acceleration energy of 85 keV with a dose of 3×10¹³ cm⁻², in the same manner as the first example. Thereafter, impurity ions of Art were implanted at a room temperature and acceleration energy of 70 keV with a dose of 1×10¹⁵ cm⁻², which was greater than that in the first example, so as to manufacture a silicon carbide semiconductor device having a breakdown voltage of 1200 volts, while the other manufacturing conditions were the same as those in the first example.

The second example had a result that the silicon carbide semiconductor device had a proportion of 3C that was 85% obtained such that a SiC surface was analyzed by EBSD to calculate the proportion of the crystal phase. Evaluation revealed that the silicon carbide semiconductor device of the second example had the greater proportion of 3C than the first example due to the increased dose of Art.

### Third Example

The third example executed a two-stage ion implantation including a first ion implantation of P⁺ implanted at a room temperature and acceleration energy of 200 keV with a dose of 4×10¹³ cm⁻², and a second ion implantation of P⁺ implanted at a room temperature and acceleration energy of 85 keV with a dose of 3×10¹³ cm⁻², in the same manner as the first example. Thereafter, impurity ions of Sit were implanted at a room temperature and acceleration energy of 70 keV with a dose of 2×10¹⁴ cm⁻² with the ionic species changed from that in the first example, so as to manufacture a silicon carbide semiconductor device having a breakdown voltage of 1200 volts, while the other manufacturing conditions were the same as those in the first example.

The third example had a result that the silicon carbide semiconductor device had a proportion of 3C that was 70% obtained such that a SiC surface was analyzed by EBSD to calculate the proportion of the crystal phase. Evaluation revealed that the silicon carbide semiconductor device of the third example had the proportion of 3C that was equivalent to that of the first example when the impurity ions of Sit were implanted instead of Art.

### Fourth Example

The fourth example executed a two-stage ion implantation including a first ion implantation of P⁺ implanted at a room temperature and acceleration energy of 200 keV with a dose of 4×10¹³ cm⁻², and a second ion implantation of P⁺ implanted at a room temperature and acceleration energy of 85 keV with a dose of 3×10¹³ cm⁻², in the same manner as the first example. Thereafter, impurity ions of Si⁺ were implanted at a room temperature and acceleration energy of 70 keV with a dose of 1×10¹⁵ cm⁻², which was greater than that in the first example, with the element to be implanted changed from that in the first example, so as to manufacture a silicon carbide semiconductor device having a breakdown voltage of 1200 volts, while the other manufacturing conditions were the same as those in the first example.

The fourth example had a result that the silicon carbide semiconductor device had a proportion of 3C that was 85% obtained such that a SiC surface was analyzed by EBSD to calculate the proportion of the crystal phase. Evaluation revealed that the silicon carbide semiconductor device of the fourth example had the greater proportion of 3C than the third example due to the increased dose of Sit.

### Fifth Example

The fifth example executed a two-stage ion implantation including a first ion implantation of P⁺ implanted at a room temperature and acceleration energy of 200 keV with a dose of 4×10¹³ cm⁻², and a second ion implantation of P⁺ implanted at a room temperature and acceleration energy of 85 keV with a dose of 3×10¹³ cm⁻², in the same manner as the first example. Thereafter, carbon ions (C+) were implanted at a room temperature and acceleration energy of 70 keV with a dose of 1×10¹⁵ cm⁻² with the ionic species changed from that in the first example, so as to manufacture a silicon carbide semiconductor device having a breakdown voltage of 1200 volts, while the other manufacturing conditions were the same as those in the first example.

The fifth example had a result that the silicon carbide semiconductor device had a proportion of 3C that was 70% obtained such that a SiC surface was analyzed by EBSD to calculate the proportion of the crystal phase. Evaluation revealed that the silicon carbide semiconductor device of the fifth example had the proportion of 3C that was equivalent to that of the first example when the impurity ions of C⁺ were implanted instead of Art.

### Sixth Example

The sixth example executed a two-stage ion implantation including a first ion implantation of P⁺ implanted at a room temperature and acceleration energy of 200 keV with a dose of 4×10¹³ cm⁻², and a second ion implantation of P⁺ implanted at a room temperature and acceleration energy of 85 keV with a dose of 3×10¹³ cm⁻², in the same manner as the first example. Thereafter, impurity ions of C⁺ were implanted at a room temperature and acceleration energy of 70 keV with a dose of 3×10¹⁵ cm⁻², which was greater than that in the first example, with the element to be implanted changed from that in the first example, so as to manufacture a silicon carbide semiconductor device having a breakdown voltage of 1200 volts, while the other manufacturing conditions were the same as those in the first example.

The sixth example had a result that the silicon carbide semiconductor device had a proportion of 3C that was 85% obtained such that a SiC surface was analyzed by EBSD to calculate the proportion of the crystal phase. Evaluation revealed that the silicon carbide semiconductor device of the sixth example had the greater proportion of 3C than the fifth example due to the increased dose of C+.

### COMPARATIVE EXAMPLE

The comparative example executed a two-stage ion implantation including a first ion implantation of P⁺ implanted at a room temperature and acceleration energy of 200 keV with a dose of 4×10¹³ cm⁻², and a second ion implantation of P⁺ implanted at a room temperature and acceleration energy of 85 keV with a dose of 3×10¹³ cm⁻², in the same manner as the first example. Thereafter, n-type impurity ions of P⁺ were implanted at a room temperature and acceleration energy of 70 keV with a dose of 2×10¹⁴ cm 2 with the ionic species changed from that in the first example, so as to manufacture a silicon carbide semiconductor device having a breakdown voltage of 1200 volts, while the other manufacturing conditions were the same as those in the first example.

The comparative example had a result that the silicon carbide semiconductor device had a drain-source leakage current (Idss) that was 1×10⁻⁵ A. Evaluation revealed that the leakage current was increased as compared with the first example when the impurity ions P⁺ were implanted instead of Ar⁺.

Next, seventh to ninth examples are described below with reference to table 2.

TABLE 2

| | | | ACCELERATION | | LEAKAGE |
|---|---|---|---|---|---|
| | | ION | ENERGY | DOSE | CURRENT |
| | TEMPERATURE | SPECIES | [keV] | [cm⁻²] | [A] |
| SEVENTH | ROOM | P⁺ | 120 | 5 × 10¹³ | 5 × 10⁻⁶ |
| EXAMPLE | TEMPERATURE | | | | |
| | ROOM | Ar⁺ | 70 | 2 × 10¹⁴ | |
| | TEMPERATURE | | | | |
| EIGHTH | ROOM | P⁺ | 120 | 5 × 10¹³ | 1 × 10⁻⁶ |
| EXAMPLE | TEMPERATURE | | | | |
| | ROOM | Si⁺ | 70 | 2 × 10¹⁴ | |
| | TEMPERATURE | | | | |
| NINTH | ROOM | P⁺ | 120 | 5 × 10¹³ | 1 × 10⁻⁶ |
| EXAMPLE | TEMPERATURE | | | | |
| | ROOM | C⁺ | 30 | 1 × 10¹⁵ | |
| | TEMPERATURE | | | | |

### Seventh Example

The seventh example executed a single-stage ion implantation of P⁺ implanted at a room temperature and acceleration energy of 120 keV with a dose of 5×10¹³ cm⁻² with the number of the implantation stages, the acceleration energy, and the dose changed from those in the first example. Thereafter, impurity ions of Art were implanted at a room temperature and acceleration energy of 70 keV with a dose of 2×10¹⁴ cm⁻² in the same manner as the first example, so as to manufacture a silicon carbide semiconductor device having a breakdown voltage of 1200 volts, while the other manufacturing conditions were the same as those in the first example.

The seventh example had a result that the silicon carbide semiconductor device had a drain-source leakage current (Idss) that was 5×10⁻⁶ A. Evaluation revealed that the leakage current was equivalent to that of the first example, so as to suppress the leakage current more than the comparative example.

### Eighth Example

The eighth example executed a single-stage ion implantation of P⁺ implanted at a room temperature and acceleration energy of 120 keV with a dose of 5×10¹³ cm⁻² in the same manner as the seventh example. Thereafter, impurity ions of Si⁺ were implanted at a room temperature and acceleration energy of 70 keV with a dose of 2×10¹⁴ cm⁻² with the ionic species changed from that in the seventh example, so as to manufacture a silicon carbide semiconductor device having a breakdown voltage of 1200 volts, while the other manufacturing conditions were the same as those in the first example.

The eighth example had a result that the silicon carbide semiconductor device had a drain-source leakage current (Idss) that was 1×10⁻⁶ A. Evaluation revealed that the leakage current could be suppressed much more than that in the seventh example when the impurity ions of Sit were implanted instead of Ar+. Evaluation further revealed that the cause of crystal defects was presumed to be suppressed when the crystal structure was led to turn to 3C in the case of the implantation of Sit more than the case of the implantation of Ar⁺.

### Ninth Example

The ninth example executed a single-stage ion implantation of P⁺ implanted at a room temperature and acceleration energy of 120 keV with a dose of 5×10¹³ cm⁻² in the same manner as the seventh example. Thereafter, impurity ions of C⁺ were implanted at a room temperature and acceleration energy of 30 keV with a dose of 1×10¹⁵ cm⁻² with the ionic species, the acceleration energy, and the dose changed from those in the seventh example, so as to manufacture a silicon carbide semiconductor device having a breakdown voltage of 1200 volts, while the other manufacturing conditions were the same as those in the first example.

The ninth example had a result that the silicon carbide semiconductor device had a drain-source leakage current (Idss) that was 1×10⁻⁶ A. Evaluation revealed that the leakage current could be suppressed much more than that in the seventh example when the impurity ions of C⁺ were implanted instead of Ar⁺. Evaluation further revealed that the cause of crystal defects was presumed to be suppressed when the crystal structure was led to turn to 3C in the case of the implantation of C⁺ more than the case of the implantation of Art.

### Second Embodiment

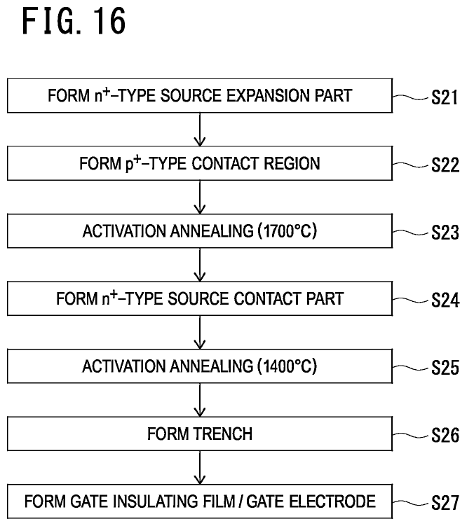

A silicon carbide semiconductor device according to a second embodiment has a configuration similar to that of the silicon carbide semiconductor device according to the first embodiment illustrated in FIG. 1. A method of manufacturing the silicon carbide semiconductor device according to the second embodiment differs from the manufacturing method according to the first embodiment in including an activation annealing step in step S23 for the ion-implanted regions other than the source contact part 72 and including an activation annealing step in step S25 for the source contact part 72 executed independently of each other, as shown in FIG. 16.

The steps executed before an n⁺-type-source-expansion-part forming step in step S21 shown in FIG. 16 are substantially the same as those in the method of manufacturing the silicon carbide semiconductor device according to the first embodiment, and overlapping explanations are not repeated below. The n⁺-type-source-expansion-part forming step in step S21 shown in FIG. 16 is substantially the same as the n⁺-type-source-expansion-part forming step in step S11 shown in FIG. 4, which implants the n-type impurity ions such as P at a room temperature so as to form the n⁺-type source expansion part 71, as shown in FIG. 9.

A p⁺-type-contact-region forming step in step S22 shown in FIG. 16 is substantially the same as that in step S13 shown in FIG. 4, which implants the p-type impurity ions so as to form the p⁺-type base contact regions 8a and 8b, as shown in FIG. 11. At this point, the n⁺-type source contact part 72 is not formed yet.

An activation annealing step in step S23 shown in FIG. 16 is substantially the same as that in step S14 shown in FIG. 4, which executes the activation annealing at a temperature in a range of about 1600° C. or higher and 1900° C. or lower, for example, so as to collectively activate the p-type impurity ions or the n-type impurity ions implanted into the regions such as the first buried regions 4a and 4c, the gate-bottom protection region 4b, the second buried regions 5a and 5b, the source expansion part 71, and the base contact regions 8a and 8b. At this point, the n⁺-type source contact part 72 is not formed yet.

An n⁺-type-source-contact-part forming step in step S24 shown in FIG. 16 is substantially the same as that in step S12 shown in FIG. 4, which implants the impurity ions of Ar, Si, or C at a room temperature so as to form the n⁺-type source contact part 72, as shown in FIG. 10. The damage during the ion implantation breaks 4H-SiC included in the source contact part 72 so as to form an amorphous structure.

An activation annealing step in step S25 shown in FIG. 16 is executed at a lower temperature than in step S23 shown in FIG. 16, which is in a range of about 1300° C. or higher and 1500° C. or lower, for example, so as to activate the n-type impurity ions implanted into the source contact part 72. This step leads the amorphous structure in the source contact part 72 to be recrystallized to turn to 3C-SiC, so as to form the source contact part 72 including 3C-SiC.

A trench forming step in step S26 shown in FIG. 16 is substantially the same as that in step S15 shown in FIG. 4, which selectively digs the trench 10 in the depth direction from the top surface of the source contact part 72 by dry etching, for example, as shown in FIG. 12.

A gate-insulating-film/gate-electrode forming step in step S27 shown in FIG. 16 is substantially the same as that in step S16 shown in FIG. 4, which buries the insulated gate electrode structure (11, 12) implemented by the gate insulating film 11 and the gate electrode 12 inside the trench 10, as illustrated in FIG. 13. The other steps followed by the gate-insulating-film/gate-electrode forming step in step S27 shown in FIG. 16 are substantially the same as those in the method of manufacturing the silicon carbide semiconductor device according to the first embodiment, and overlapping explanations are not repeated below.

The method of manufacturing the silicon carbide semiconductor device according to the second embodiment can provide the trench-gate silicon carbide semiconductor device that can lead the respective source regions 7a and 7b to be in ohmic contact with the source electrode (14, 15), and further suppress a drain-source leakage current, as in the case of the method of manufacturing the silicon carbide semiconductor device according to the first embodiment.

Further, the method of manufacturing the silicon carbide semiconductor device according to the second embodiment executes the activation annealing step in step S23 for the ion-implanted regions other than the source contact part 72 independently of the activation annealing step in step S25 for the source contact part 72. Although the crystal defects of 3C-SiC in the source contact part 72 are caused upon the recrystallization of the amorphous structure during the activation annealing, the manufacturing method according to the present embodiment executes the activation annealing in step S25 at a lower temperature than in step S23, so as to decrease or suppress a transmission of crystal defects from the source contact part 72 toward the source expansion part 71.

### Third Embodiment

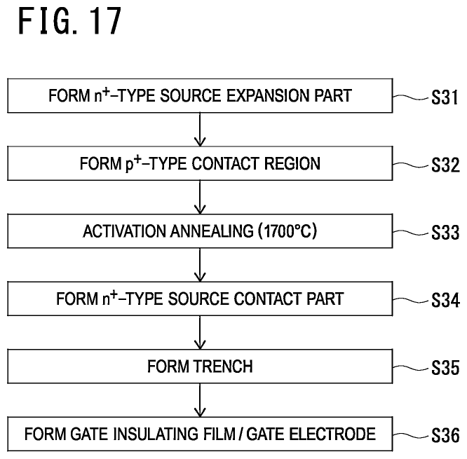

A silicon carbide semiconductor device according to a third embodiment has a configuration similar to that of the silicon carbide semiconductor device according to the first embodiment illustrated in FIG. 1. A method of manufacturing the silicon carbide semiconductor device according to the third embodiment differs from the manufacturing method according to the first embodiment in that post deposition annealing (PDA) in a gate-insulating-film/gate-electrode forming step in step S36 concurrently functions as the activation annealing for the source contact part 72, as shown in FIG. 17.

The steps executed before an n⁺-type-source-expansion-part forming step in step S31 shown in FIG. 17 are substantially the same as those in the method of manufacturing the silicon carbide semiconductor device according to the first embodiment, and overlapping explanations are not repeated below. The n⁺-type-source-expansion-part forming step in step S31 shown in FIG. 17 is substantially the same as the n⁺-type-source-expansion-part forming step in step S11 shown in FIG. 4, which implants the n-type impurity ions such as P at a room temperature so as to form the n⁺-type source expansion part 71, as shown in FIG. 9.

A p⁺-type-contact-region forming step in step S32 shown in FIG. 17 is substantially the same as that in step S13 shown in FIG. 4, which implants the p-type impurity ions so as to form the p⁺-type base contact regions 8a and 8b, as shown in FIG. 11. At this point, the n⁺-type source contact part 72 is not formed yet.

An activation annealing step in step S33 shown in FIG. 17 is substantially the same as that in step S14 shown in FIG. 4, which executes the activation annealing at a temperature in a range of about 1600° C. or higher and 1900° C. or lower, for example, so as to collectively activate the p-type impurity ions or the n-type impurity ions implanted into the regions such as the first buried regions 4a and 4c, the gate-bottom protection region 4b, the second buried regions 5a and 5b, the source expansion part 71, and the base contact regions 8a and 8b. At this point, the n⁺-type source contact part 72 is not formed yet.

An n⁺-type-source-contact-part forming step in step S34 shown in FIG. 17 is substantially the same as that in step S12 shown in FIG. 4, which implants the impurity ions of Ar, Si, or C at a room temperature so as to form the n⁺-type source contact part 72, as shown in FIG. 10. The damage during the ion implantation breaks 4H-SiC included in the source contact part 72 so as to form an amorphous structure.

A trench forming step in step S35 shown in FIG. 17 is substantially the same as that in step S15 shown in FIG. 4, which selectively digs the trench 10 in the depth direction from the top surface of the source contact part 72 by dry etching, for example, as shown in FIG. 12.

A gate-insulating-film/gate-electrode forming step in step S36 shown in FIG. 17 is substantially the same as that in step S16 shown in FIG. 4, which deposits the gate insulating film 11 inside the trench 10, as illustrated in FIG. 13. The annealing is executed upon the formation of the gate insulating film 11 at a temperature in a range of 900° C. or higher and 1350° C. or lower, for example, which is lower than the temperature at the activation annealing in step S33 in FIG. 17. The execution of the annealing activates the n-type impurity ions implanted into the source contact part 72, and further leads the amorphous structure in the source contact part 72 to be recrystallized to turn to 3C-SiC, so as to form the source contact part 72 including 3C-SiC. Thereafter, the gate electrode 12 is buried inside the trench 10, so as to form the insulated gate electrode structure (11, 12) implemented by the gate insulating film 11 and the gate electrode 12.

The other steps followed by the gate-insulating-film/gate-electrode forming step in step S36 shown in FIG. 17 are substantially the same as those in the method of manufacturing the silicon carbide semiconductor device according to the first embodiment, and overlapping explanations are not repeated below.

The method of manufacturing the silicon carbide semiconductor device according to the third embodiment can provide the trench-gate silicon carbide semiconductor device that can lead the respective source regions 7a and 7b to be in ohmic contact with the source electrode (14, 15), and further suppress a drain-source leakage current, as in the case of the method of manufacturing the silicon carbide semiconductor device according to the first embodiment.

Further, the method of manufacturing the silicon carbide semiconductor device according to the third embodiment executes the annealing in the gate-insulating-film/gate-electrode forming step in step S36 at a lower temperature than the activation annealing in step S33, so as to decrease or suppress a transmission of crystal defects of 3C-SiC from the source contact part 72 toward the source expansion part 71, regardless of whether the crystal defects tend to be caused upon the recrystallization of the amorphous structure during the activation annealing. Further, the manufacturing method uses the annealing executed in the gate-insulating-film/gate-electrode forming step in step S36 that can concurrently function as the activation annealing for the source contact part 72, so as to avoid an increase in the number of manufacturing steps.

### Other Embodiments

As described above, the invention has been described according to the first to third embodiments, but it should not be understood that the description and drawings implementing a portion of this disclosure limit the invention. Various alternative embodiments of the present disclosure, examples, and operational techniques will be apparent to those skilled in the art from this disclosure.

For example, the first to third embodiments have been illustrated with the MOSFET as the semiconductor device, but may also be applied to a case of using an insulated gate bipolar transistor (IGBT) including a p⁺-type collector region instead of the n⁺-type drain region 1. Alternatively, the first to third embodiments may be applied to a reverse conducting IGBT (RC-IGBT or a reverse blocking IGBT (RB-IGBT), instead of a simple IGBT.

As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A method of manufacturing a silicon carbide semiconductor device, comprising:
forming a base region of a second conductivity-type including silicon carbide on a top surface side of a drift layer of a first conductivity-type including silicon carbide;
forming a main region of the first conductivity-type including silicon carbide on a top surface side of the base region;
digging a trench to penetrate the main region and the base region;
depositing a gate insulating film in the trench;
burying a gate electrode inside the trench with the gate insulating film interposed; and
forming a main electrode so as to be in contact with the main region,
wherein the forming the main region includes:
implanting impurity ions of the first conductivity-type at a room temperature so as to form a first region including a 4H-structure on the top surface side of the base region; and
implanting impurity ions of at least one of silicon, carbon, or argon at a room temperature so as to form a second region including a 3C-structure to be in contact with the main electrode on a top surface side of the first region.

2. The method of manufacturing the silicon carbide semiconductor device of claim 1, wherein the impurity ions of the first conductivity-type are either phosphorus or nitrogen.

3. The method of manufacturing the silicon carbide semiconductor device of claim 1, wherein a dose of the impurity ions of the first conductivity-type when implanted is 5×10¹³ cm⁻² or less.

4. The method of manufacturing the silicon carbide semiconductor device of claim 1, wherein the impurity ions implanted for forming the second region are either silicon or carbon.

5. The method of manufacturing the silicon carbide semiconductor device of claim 1, wherein the impurity ions implanted for forming the second region are argon.

6. The method of manufacturing the silicon carbide semiconductor device of claim 1, wherein a top surface of the gate electrode located at a position in contact with the gate insulating film is deeper than a bottom surface of the second region and shallower than a bottom surface of the first region.

7. A silicon carbide semiconductor device comprising:
a drift layer of a first conductivity-type including silicon carbide;
a base region of a second conductivity-type including silicon carbide provided on a top surface side of the drift layer;
a main region of the first conductivity-type including silicon carbide provided on a top surface side of the base region;
a gate insulating film provided in a trench penetrating the main region and the base region;
a gate electrode buried inside the trench with the gate insulating film interposed; and
a main electrode provided to be in contact with the main region,
wherein the main region includes;
a first region including a 4H-structure on the top surface side of the base region; and
a second region provided to be in contact with the main electrode on a top surface side of the first region and including a 3C-structure with a proportion of 70% or higher at least on top surface side of the second region.

8. The silicon carbide semiconductor device of claim 7, wherein the second region includes argon.

9. The silicon carbide semiconductor device of claim 7, wherein the proportion of the 3C-structure at least on the top surface side of the second region is 85% or higher.
